(19) United States
(12) Patent Application Publication
(10) Pub. No.: US 2008/0197867 A1
(43) Pub. Date: Aug. 21, 2008

(54) SOCKET SIGNAL EXTENDER

(75) Inventors: Sudhir Wokhlu, Plano, TX (US); Toby Obadiah Byrd, Honey Grove, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/675,558

(22) Filed: Feb. 15, 2007

(51) Int. Cl. G01R 1/04

(52) U.S. Cl. 324/755

(57) ABSTRACT

A socket signal extender (SSE), and a system and method of testing an assembled device under test (DUT) board employing an SSE. In one embodiment, the SSE includes a cover having a portion configured to fit within a test socket. The portion is free of logic and includes electrical conductors configured to provide an electrical connection to contacts of the test socket.

### TECHNICAL FIELD OF THE INVENTION

The invention is directed, in general, to testing of hardware designed to test a semiconductor device and, more specifically, to an apparatus that provides access to contacts of a test socket for the semiconductor device that is coupled to a test board.

### BACKGROUND OF THE INVENTION

Semiconductor devices, such as those used in a wireless apparatus, are tested to verify a variety of things, including construction, design and operating parameters. One way to test a semiconductor device after fabrication is to place it in a test socket that is connected to a test board. The test board includes hardware that has been designed to test, for example, operating parameters of the semiconductor device. The hardware or hardware configuration may vary depending on the semiconductor device to test or the specific test for it.

The test socket has a cavity with multiple contacts located at the base thereof that are connected to the hardware on the test board. Typically, the contacts are spring-loaded contacts, such as pogo-pins. The semiconductor device is placed in the test socket and connected to the hardware on the test board via the test socket contacts. Test signals, such as voltages, currents or Boundary Scan digital data (compliant with Institute of Electrical and Electronic Engineers, or IEEE, standard 1149.4) may then be applied to the test board and resulting measurements taken to test the semiconductor device.

When testing a semiconductor device, problems frequently develop with the test socket or test board. For example, intermittent or open contact issues between the test socket contacts and the test board often create testing problems that require time and engineering resources to resolve. Additionally, the hardware or hardware configuration on the test board may have failures that create testing problems for the semiconductor device. These problems affect the debugging of the semiconductor device which delays the time-to-market of the semiconductor device.

Accordingly, what is needed in the art is an apparatus and method to allow testing of a test board after assembly and the connection between a test socket and the test board before the semiconductor device is placed in the test socket.

### SUMMARY OF THE INVENTION

To address the above-discussed deficiencies of the prior art, the invention provides a socket signal extender (SSE), a method of testing a device-under-test (DUT) board, and a system for testing a DUT board. In one embodiment, the SSE includes a cover having a portion configured to fit within a test socket. The portion is free of logic and includes electrical conductors configured to provide an electrical connection to contacts of the test socket.

In another aspect, the invention provides a method of testing a DUT board. In one embodiment, the method includes (1) providing an accessible electrical connection to contacts of a test socket via electrical conductors of a socket signal extender (SSE). The contacts are connected to circuitry of the DUT board and the SSE includes a cover with a portion that fits within the test socket. The portion is free of logic and includes the electrical conductors. The method also includes (2) applying a test signal to the circuitry via the electrical conductors of the SSE.

In yet another aspect, the invention provides a system for testing an assembled DUT board using a SSE. In one embodiment, the system includes: (1) a test socket having a cavity and contacts, wherein the contacts are coupled to circuitry of the DUT board and (2) a SSE including a cover having a portion configured to fit within said cavity of said test socket. The portion is free of logic and includes electrical conductors configured to provide an electrical connection between the contacts of the test socket and a test instrument.

In still another aspect, the invention provides another embodiment of a SSE, including a cover having a portion that protrudes from the cover and is configured to fit within a cavity of a test socket as the cover sits on sides of the test socket that form the cavity. The portion electrically consists of electrical conductors that pass through the cover and the portion. Each of the electrical conductors have a first end that extends past the portion and a second end that extends past the cover. When the cover is placed on the sides of the test socket, the first ends provide an electrical connection to the contacts of the test socket and the second ends provide an accessible connection to the contacts.

### BRIEF DESCRIPTION OF THE DRAWINGS

For a more complete understanding of the invention, reference is now made to the following descriptions taken in conjunction with the accompanying drawings, in which:

FIG. 1 illustrates a block diagram of an embodiment of an SSE constructed according to the principles of the present invention;

FIG. 2 illustrates a diagram of an embodiment of a system for testing an assembled device under test (DUT) board using an SSE constructed according to the principles of the invention; and

FIG. 3 illustrates a flow diagram of an embodiment of a method of testing a DUT board carried out according to the principles of the present invention.

### DETAILED DESCRIPTION

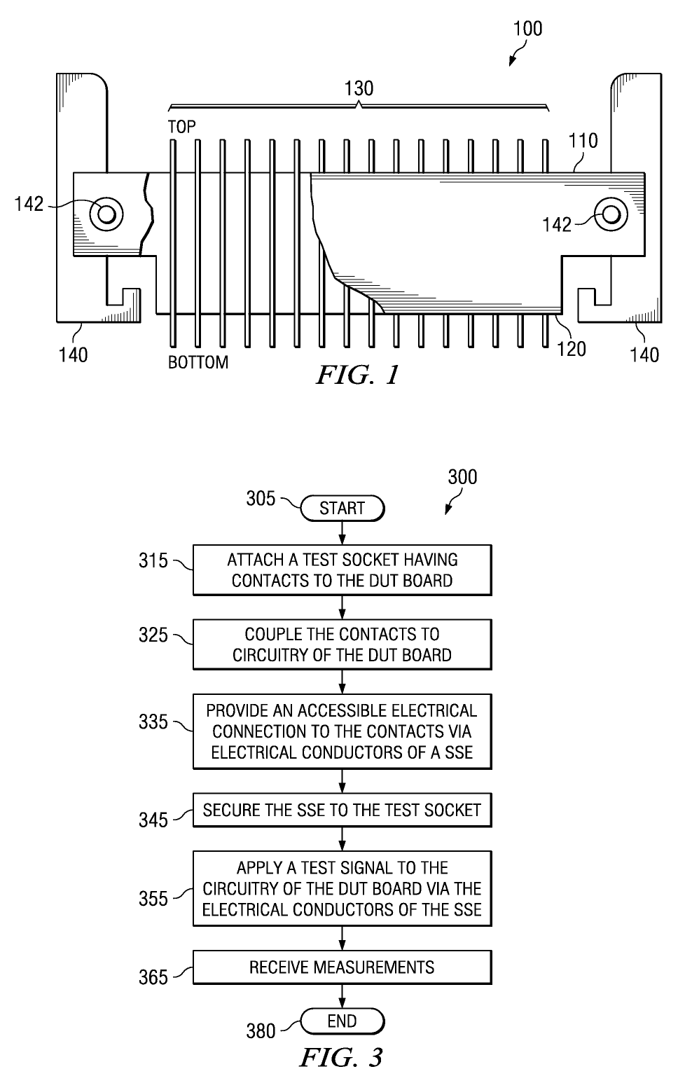

FIG. 1 illustrates a block diagram of an embodiment of an SSE 100 constructed according to the principles of the present invention. The SSE 100 includes a cover 110 having a portion 120 configured to fit within an opening, or cavity, of a test socket. The cover 110 is constructed of non-conducting material and is sized to sit on the sides of the test socket that form the cavity. The portion 120 fits within the cavity and includes electrical conductors 130 configured to provide an electrical connection to contacts of the test socket when the portion 120 is placed in the cavity. The electrical conductors 130 allow access to the contacts of the test socket at the base of the cavity when a semiconductor device is not placed in the test socket.

The portion 120 is free of logic wherein logic is circuitry configured to perform switching operations. In other words, the portion 120 does not include any logic circuitry that is capable of performing switching. For example, the portion 120 does not include transistors, combinatorial circuits, gates, semiconductor chips, etc. As such, the portion 120 is incapable of performing logical or switching operations.

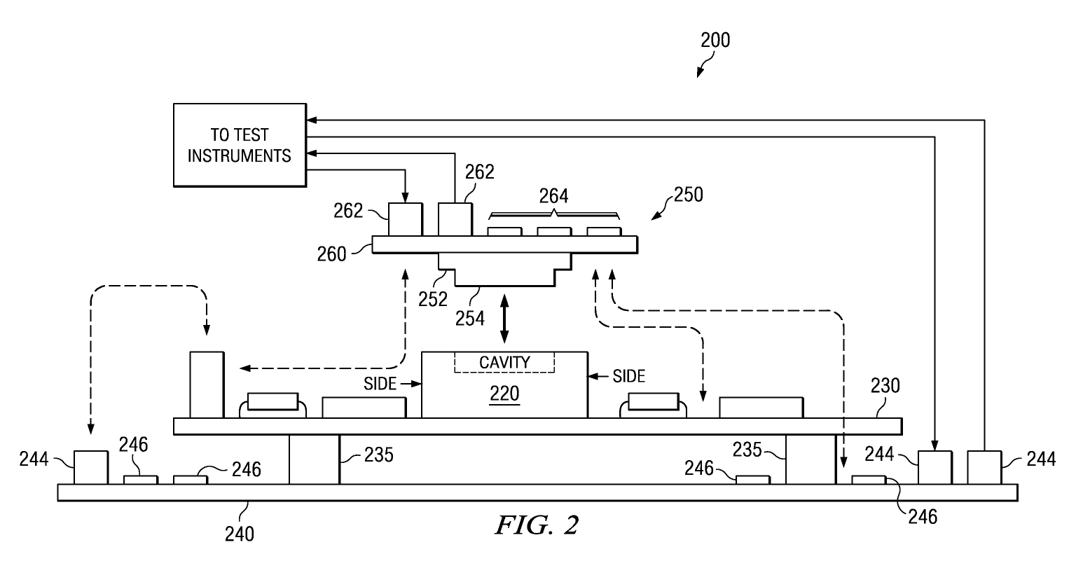

The electrical conductors 130 are an array of through-hole pins that extend through and past the cover 110 and the portion 120. At one end (the bottom end as FIG. 1 is oriented), the electrical conductors 130 extend past the portion 120 and connect to the contacts of the test socket. At the opposite end (the top end as FIG. 1 is oriented), the electrical conductors 130 extend past the cover 110 and can be used to provide connections to one or more test instruments. As discussed with respect to FIG. 2, the extension of the electrical conductors 130 past the cover 110 may be used to coupled the SSE 100 to a probe board. The probe board can be used to provide an interface between the electrical conductors 130 and the test instruments. An SSE having a probe board is discussed in more detail with respect to FIG. 2.

The electrical conductors 130 provide access to the contacts of the test socket even after the test socket is mounted to a test board. The electrical conductors 130 are arranged to connect to the contacts of the test socket. Typically, the test socket contacts are spring-loaded contacts in a ball-grid array (BGA). Accordingly, the electrical conductors 130 are configured to interface with the BGA contacts of the test socket. For example, the electrical conductors 130 are appropriately spaced to interface with the BGA sockets depending on a pitch of the array. As such, depending on the pitch of the BGA of a particular test socket, such as 0.4, 0.5, 0.8 and 1.0 mm, the electrical conductors 130 are configured appropriately.

The cover 110 further includes a latching mechanism 140 configured to secure the SSE 100 to the test socket and maintain the connection of the electrical conductors 130 to the test socket contacts. The latching mechanism 140 is a conventional mechanism with two latches that are spring-coupled to the cover 110 for securing the SSE 100 to the test socket. The two latches of the latching mechanism 140 are coupled to the cover 110 via pins 142 that allow the latches to move with respect to the cover 110. The latching mechanism 140 provides sufficient downward pressure on the SSE 100 to maintain a connection between the electrical conductors 130 and the contacts of the test socket. As noted above, the contacts of the test socket are typically spring-loaded pins, and the latching mechanism 140 typically presses the electrical conductors 130 into the spring-loaded pins to maintain the electrical connection. One skilled in the art will understand the latching mechanism 140 and understand that other latching mechanisms may be used. For example, in some embodiments, one side of the cover 110 may be hinged-coupled to the test socket and a single latch employed to secure the opposite side of the cover 110 to the test socket.

FIG. 2 illustrates a diagram of an embodiment of a test system for testing an assembled DUT board using an SSE constructed according to the principles of the invention. The system 200 includes a test socket 220, a test board 230, a test bed 240 and a SSE 250.

The test system 200 is configured to allow the application of test signals designed for post-assembly testing of the test board 230 and to measure the responses. The test signals may be supplied from various sources including conventional test instruments. A computer employing a sequence of operating instructions may be used to direct testing of the test board. The computer can direct the sources or a single source to provide test signals to the test bed 240 or the SSE 250. The source 216 may include a current source, a voltage source or a JTAG compliant source configured to provides Boundary Scan technology in accordance with IEEE 1149.4. Each of these sources may be a separate component or may be contained in a single enclosure. The test instruments may be coupled to the test bed 240 and the SSE 250 via SubMiniature version A (SMA) connections.

The test socket 220 may be a conventional test socket that is attached to the test board 230 and has electrical contacts that are connected to the hardware of the test board 230. One skilled in the art will understand the test socket 220 and the electrical and mechanical coupling of the test socket 220 to the test board 230. The test socket 220 includes a cavity wherein a semiconductor device is placed for testing. The test socket 220 includes contacts (not illustrated) at the base of the cavity that connect the semiconductor device to the test board 230 when testing the semiconductor device. Instead of the semiconductor device, the SSE 250 can be placed in the cavity to allow testing of the assembled test board 230 and the connections between the contacts of the test socket 220 and the test board 230. Thus, the hardware and the connections of the test board 230 and the test socket 220 can be tested before the semiconductor is even ready to be tested. This reduces the overall time needed to verify the semiconductor device and deliver it to market.

The test board 230 is typically a printed circuit board (PCB) with appropriate hardware sized and configured to test the semiconductor device. The test board 230 may be a typical DUT board used to test a semiconductor device. The test board 230 may be a characterization board for characterization testing of the semiconductor device. The test board 230 may also be a system board to test the functionality of the semiconductor device. The test board 230 is connected to the test bed 240 by standard connectors 235 configured to provide an electrical path therebetween.

The test bed 240 may be a conventional test bed such as a JTAG DOT 4 compliant test bed. The test bed 240 includes connection points 244 for connecting to the test instruments and to the test board 230. The connection points 244 may be conventional SMA connectors. The test bed 240 also includes IEEE 1149.4 compliant System Test Access (STA) devices, denoted 246, such as an STA 400, commercially available from National Semiconductor Corporation of Santa Clara, Calif., that allows sourcing or measuring of signals through IEEE 1149.4 compliant controllable analog busses. Test signals and measurements can be routed through the test bed 240 via the connecting points 244.

The SSE 250 includes a cover 252 having a portion 254 that fits in the cavity of the test socket 220. The SSE 250 is constructed similar to the SSE 100 in FIG. 1 except the SSE 250 does not include a latching mechanism. Of course, in some embodiments, the SSE 250 may include a latching mechanism including the latching mechanism 140 of FIG. 1. The SSE 250, therefore, includes electrical conductors (not illustrated) that are constructed as the electrical conductors 130 of the SSE 100 in FIG. 1.

The portion 254 electrically consists of the electrical conductors. Accordingly, the only electrical components of the portion 254 are the electrical conductors. The portion 254 does not include logic circuitry. In other words, the portion 254 is free of logic. As such, the portion 254 does not include transistors, combinatorial circuits, gates, etc. Thus, the portion 254 is incapable of performing logical operations or switching.

Unlike the SSE 100, the SSE 250 includes a probe board 260 coupled thereto. The probe board 260 may be a PCB having through-holes that the electrical conductors pass through. The electrical conductors may be soldered in the through-holes to electrically couple the probe board 260 to the SSE 250. As such, the through-holes of the probe board 260 are arranged in a BGA having a pitch and configuration that matches the BGA of the contacts of the test socket 220. The probe board 260 may sit on top of the cover 252 as the electrical conductors pass through the through-holes of the probe board 260.

The probe board 260 includes connecting nodes 262 coupled to at least one of the electrical conductors by an electrical connector or connectors (not illustrated). The electrical connectors may be electrical traces on the PCB board. The connecting nodes 262 may be SMA connectors or other connectors configured to provide an interface to, for example, the test instruments. The number of connecting nodes 262 and the type of nodes can vary. The probe board 260 also includes STA chips 264 such as the STA 400 chips that are coupled to the electrical conductors by the electrical connectors.

Connections from the STA chips 264 to the electrical conductors may be determined based on the desired tests to be performed on the test board 230. The connections to the electrical conductors may be determined manually or may be determined automatically. When determined automatically, a sequence of operating instructions may be used to determine the connections based on schematic netlist of the test board 230.

FIG. 3 illustrates a flow diagram of an embodiment of a method 300 of testing a device under test (DUT) board carried out according to the principles of the present invention. The method 300 begins in a step 305 with an intent to test a DUT board.

Thereafter, a test socket having contacts is attached to the DUT board in step 315. The test socket may be fixed to the DUT board using screws or another conventional attaching method.

After attaching the test socket, the contacts of the test socket are coupled to circuitry of the DUT board in a step 325. The contacts may be spring-loaded contacts that fit within a BGA of the DUT board. Other means of connecting the contacts to the circuitry of the DUT board may also be employed. Of course, one skilled in the art will understand that the DUT board may already have a test socket attached to the DUT board and the contacts connected to the DUT board circuitry when beginning testing of the DUT board.

After coupling the contacts, an accessible electrical connection to the contacts via electrical conductors of a socket signal extender (SSE) SSE is provided in a step 335. The SSE has a cover with a portion configured to fit within a cavity of the test socket. The electrical conductors pass through the SSE and provide the accessible electrical connection to the contacts of the test socket when the SSE is placed on the test socket. The electrical conductors may be an array of through-hole pins that are arranged to connect to each of the test socket contacts and placing the SSE on the test socket enables a conductive path to each of the contacts. The electrical conductors, therefore, allow access to the test socket contacts when the SSE is placed on the test socket.

Thereafter, the SSE is secured to test socket in a step 345. The SSE may be secured using a latching mechanism as discussed with respect to FIG. 1. Securing the SSE may be used to apply the appropriate amount of pressure to maintain a connection between the electrical conductors of the SSE and the contacts of the test socket. For example, the contacts of the test socket may be spring-loaded pins and the securing presses the electrical conductors into the spring-loaded pins to maintain the electrical connection.

A test signal is then applied to the circuitry of the DUT board via the electrical conductors of the SSE is a step 355. The test signals may be applied to the electrical conductors via a probe board coupled thereto. Test instruments can be connected to connecting nodes of the probe board wherein at least one is connected to at least one electrical conductor of the SSE. The probe board may be a PCB and the connecting node can be a SMA connector. 14. The probe board further may also include one or more JTAG compliant test devices. The JTAG test devices can be coupled to multiple of electrical conductors to provide test signals.

After applying the test signals, measurements are then received in a step 365. The measurements may be received by the test instruments via the connecting nodes of the probe board. Additionally, the measurements may be received from the connecting points of a test bed coupled to the DUT board. The method 300 ends in a step 380.

Those skilled in the art to which the invention relates will appreciate that other and further additions, deletions, substitutions and modifications may be made to the described embodiments without departing from the scope of the invention.

What is claimed is:

1. A socket signal extender (SSE), comprising:
a cover having a portion configured to fit within a test socket, wherein said portion is free of logic and includes electrical conductors configured to provide an electrical connection to contacts of said test socket.

2. The SSE as recited in claim 1 wherein said electrical conductors are an array of through-hole pins arranged to connect to each of said contacts of said test socket.

3. The SSE as recited in claim 1 wherein said cover further includes a latching mechanism configured to secure said SSE to said test socket.

4. The SSE as recited in claim 3 wherein said contacts of said test socket are spring-loaded pins and said latching mechanism presses said electrical conductors into said spring-loaded pins to maintain said electrical connection.

5. The SSE as recited in claim 1 further comprising a probe board coupled to said cover and including a connecting node coupled to at least one of said electrical conductors by an electrical connector.

6. The SSE as recited in claim 5 wherein said probe board is a printed circuit board (PCB) and said connecting node is a SubMiniature version A (SMA) connector.

7. The SSE as recited in claim 5 wherein said probe board further includes a JTAG compliant test device couplable to multiple of said electrical conductors.

8. A method of testing a device under test (DUT) board, comprising:
providing an accessible electrical connection to contacts of a test socket via electrical conductors of a socket signal extender (SSE), said contacts connected to circuitry of said DUT board and said SSE including a cover with a portion that fits within said test socket, said portion free of logic and including said electrical conductors; and
applying a test signal to said circuitry via said electrical conductors of said SSE.

9. The method as recited in claim 8 wherein said electrical conductors are an array of through-hole pins arranged to connect to each of said contacts of said test socket and said providing includes placing said portion of said SSE in a cavity of said test socket to enable a conductive path to said each of said contacts.

10. The method as recited in claim 8 further comprising securing said SSE to said test socket.

11. The method as recited in claim 10 wherein said contacts of said test socket are spring-loaded pins and said securing presses said electrical conductors into said spring-loaded pins to maintain said electrical connection.

12. The method as recited in claim 8 wherein said SSE further includes a probe board coupled to said cover and said applying includes coupling test equipment to a connecting node of said probe board, said connecting node coupled to at least one of said electrical conductors by an electrical connector.

13. The method as recited in claim 12 wherein said probe board is a printed circuit board (PCB) and said connecting node is a SubMiniature version A (SMA) connector.

14. The method as recited in claim 12 wherein said probe board further includes a JTAG compliant test device and said applying includes coupling said JTAG compliant test device to multiple of said electrical conductors.

15. A system for testing an assembled device under test (DUT) board using a socket signal extender (SSE), comprising:
a test socket having a cavity and contacts, said contacts coupled to circuitry of said DUT board; and
a SSE including:
a cover having a portion configured to fit within said cavity of said test socket, wherein said portion is free of logic and includes electrical conductors configured to provide an electrical connection between said contacts of said test socket and a test instrument.

16. The system recited in claim 15 wherein said electrical conductors are an array of through-hole pins arranged to connect to each of said contacts of said test socket.

17. The system recited in claim 15 wherein said cover further includes a latching mechanism configured to secure said SSE to said test socket.

18. The system recited in claim 17 wherein said contacts of said test socket are spring-loaded pins and said latching mechanism presses said electrical conductors into said spring-loaded pins to maintain said electrical connection.

19. The system recited in claim 15 further comprising a probe board coupled to said cover and including at least one connecting node coupled to at least one of said electrical conductors by an electrical connector, said at least one connecting node couplable to said test instrument.

20. The system recited in claim 19 wherein said probe board is a printed circuit board (PCB) and said connecting node is a SubMiniature version A (SMA) connector.

21. The system recited in claim 19 wherein said probe board further includes a JTAG compliant test device coupled to multiple of said electrical conductors.

22. The system recited in claim 15 further comprising a test bed electrically coupled to said DUT board, said test bed including a connection point couplable to said test instrument.

23. A socket signal extender (SSE), comprising:
a cover having a portion that protrudes therefrom and is configured to fit within a cavity of a test socket as said cover sits on sides of said test socket that form said cavity, said portion electrically consisting of electrical conductors that pass through said cover and said portion, each of said electrical conductors having a first end that extends past said portion and a second end that extends past said cover, said first ends configured to provide an electrical connection to said contacts of said test socket and said second ends configured to provide an accessible connection to said contacts when said cover sits on said sides of said test socket.
